(19) United States
(12) Patent Application Publication
(10) Pub. No.: US 2008/0013752 A1
(43) Pub. Date: Jan. 17, 2008

(54) Audio entertainment system equalizer and method

(76) Inventor: Peter A. Stephens, Kokomo, IN (US)

Correspondence Address: DELPHI TECHNOLOGIES, INC., M/C 480-410-202, PO BOX 5052, TROY, MI, 48007, US

(21) Appl. No.: 11/484,215

(22) Filed: Jul. 11, 2006

(51) Int. Cl. H03G 5/00

(52) U.S. Cl. 381/103

(57) ABSTRACT

An audio entertainment system and method for providing controlled equalization of sound from an external source is provided. The audio entertainment system includes a first audio device having an equalizer with first equalization settings and an output for providing an audio output signal. The system also includes an input for receiving audio signals from an external second audio device having second equalization settings. The second audio device inputs to the first audio device second equalization settings. The system further includes a controller for processing the equalization settings and controlling the audio output signal based on the equalization settings.

### TECHNICAL FIELD

The present invention generally relates to audio entertainment systems, such as vehicle radios, and more particularly relates to a system and method of providing coordination of equalization from external source(s).

### BACKGROUND OF THE INVENTION

Audio entertainment systems, such as vehicle radios, are typically configured with equalizers that compensate for audio path inequalities and allow personalization of music and other audio. The equalizer generally controls the sound volume for different audio frequency bands from about 20 Hz to 20 kHz. Vehicle radios are often configured with default equalization settings that provide optimal sound quality within the passenger compartment of the vehicle. In some radios, personal preference for setting equalization may be adjusted such as to allow a user to emphasize or de-emphasize low (e.g., bass), middle (e.g., mid), and high (e.g., treble) audio frequencies.

Modern audio entertainment equalizers generally have a large impact on the sound quality and may be optimized by the designer and adjusted by the user to give the best perceived sound in a given situation, such as based on the type of music, headphones, speakers, environment, etc. However, when an external device, such as a portable digital music player, is used as the audio source for another audio device, such as a radio, the equalizers for the two different devices are typically cascaded and may be contradictory. This can lead to unsatisfactory results as different external devices may call for different equalizations requiring user intervention to adjust the equalization, especially when external devices are changed, which may be distractive, particularly when used in a vehicle environment.

Referring to FIG. 1, one example of an audio entertainment system 100 having an external audio source 112 is generally illustrated for use in a vehicle, according to a conventional configuration. The audio entertainment system 100 is shown employing the external device, such as a digital music player (e.g., iPod), as an external source of audio sound (e.g., music) providing a line-level audio input signal 116 to a vehicle radio 120. The vehicle radio 120 receives audio and routes it 130 to an amplifier 132 for signal amplification. The amplified and doubly equalized audio 136 is output by speaker(s) 140.

The vehicle radio 120 typically has an equalizer 128 with equalization mode settings configured for use in the vehicle. The equalization mode settings of equalizer 128 may also be personalized by a vehicle operator. For example, the driver or a passenger in the vehicle may adjust the volume settings at different audio frequencies as desired for optimum sound quality.

The external audio source device 112 also has an equalizer 114 with equalization mode settings typically configured by its designer(s) for an environment different from the vehicle environment. The equalization settings of equalizer 114 may be also configured by the user. The equalization settings of equalizer 114 for such an external device 112 may be optimized for large open spaces, such as a particular room, or playback from headsets, etc. The vehicle equalizer 128 has equalization settings that are typically optimized for the vehicle passenger compartment. The equalization settings employed with the output audio should provide sound equalization that best fits the situation.

In a typical cascaded arrangement, the equalizer 128 of the vehicle radio 120 must compensate for the external player equalizations in addition to the user's preferences when determining the equalization settings for the audio that is output by speaker(s) 140. The external audio source 112 is generally configured with one set of desired equalization settings for the song or song genre (i.e., type), however, the vehicle radio 120 typically has a different set of equalization settings. As a result, the listener generally accepts this situation. Even if the user adjusts the equalization settings of the radio equalizer 128 for the current song, the following songs may require vastly different settings. In addition, different external players will require different EQ settings, and hence further adjustment by the user which can be distractive and annoying.

Accordingly, it is desirable to provide for an audio entertainment system that selects equalization of audio from multiple equalization selections to allow optimal sound quality from an external source. In particular, it should be able to provide for a vehicle entertainment system that incorporates the proper system and user level equalizations so as to provide optimal sound quality within the vehicle.

### SUMMARY OF THE INVENTION

In accordance with the teachings of the present invention, an audio entertainment system and method for providing controlled equalization in an audio entertainment system is provided. In accordance with one aspect of the present invention, an audio entertainment system is provided that includes a first audio device having an output for providing an audio output signal, wherein the first audio device has first equalization settings. The system also includes an input for receiving audio signals from a second audio device having second equalization settings. The second audio device inputs to the first audio device the second equalization settings. The first device of the system further includes a controller for processing the first and second equalization settings and controlling the audio output signal based on at least one of the first and second equalization settings.

According to another aspect of the present invention, an audio entertainment system is provided that includes a first audio device having first equalization settings, an input and an output for providing an audio output signal. The system also has a second audio device coupled to the first audio device for inputting an audio signal to the first audio device. The second audio device further inputs second equalization settings to the first audio device. The first device of the system further includes a controller processing the first and second equalization settings and controlling the audio output signal based on at least one of the first and second equalization settings.

According to a further aspect of the present invention, a method of generating audio at controlled equalization settings in a first audio device for an audio signal received from an external second audio device is provided. The method includes the steps of communicating an audio signal from an external second audio device to a first audio device having first equalization settings, and communicating second equalization settings from the external second audio device to the first audio device. The first and second equalization settings pertain to audio levels. The method further includes the steps of processing the first and second equalization settings in the first audio device, and generating an output audio signal based on at least one of the first and second equalization settings.

These and other features, advantages and objects of the present invention will be further understood and appreciated by those skilled in the art by reference to the following specification, claims and appended drawings.

### BRIEF DESCRIPTION OF THE DRAWINGS

The present invention will now be described, by way of example, with reference to the accompanying drawings, in which:

FIG. 1 is a block diagram generally illustrating a conventional audio entertainment system configured to receive audio from an external source with cascaded equalizations;

FIG. 2 is a block diagram of an audio entertainment system configured to receive audio and equalization settings from an external source according to one embodiment of the present invention;

FIG. 3 is a block diagram further illustrating communication of equalization and genre data in the audio entertainment system of FIG. 2; and

FIG. 4 is a flow diagram illustrating a routine for controlling equalization in an audio entertainment system according to one embodiment of the present invention.

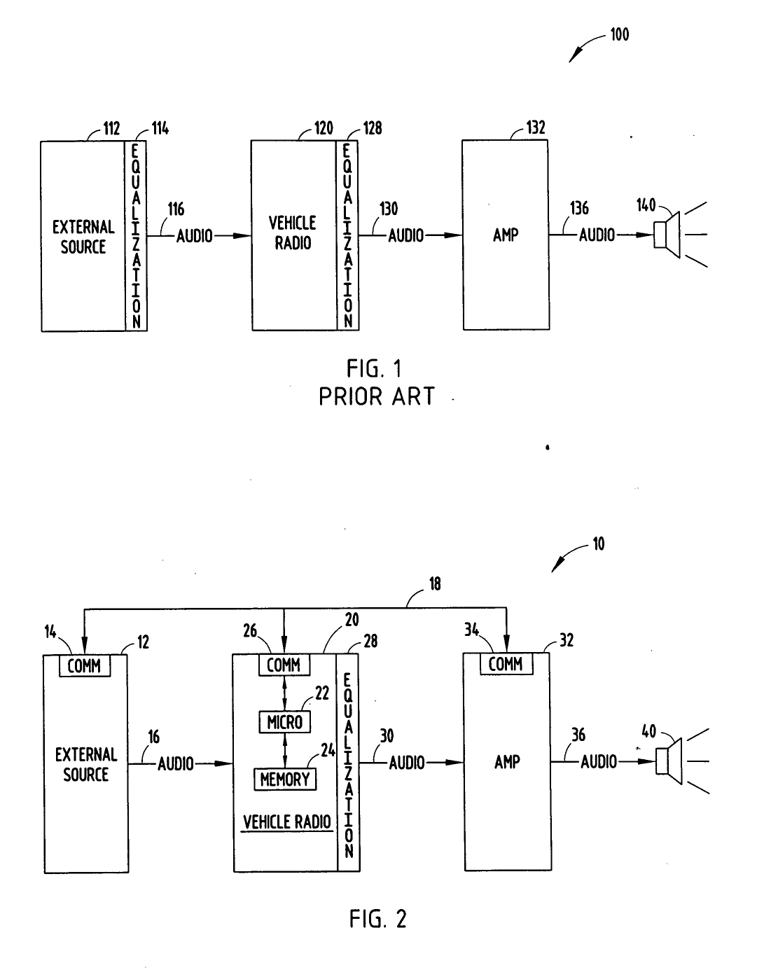

### DESCRIPTION OF THE PREFERRED EMBODIMENTS

Referring now to FIG. 2, an audio entertainment system 10 is generally illustrated having a first audio device, shown as a vehicle radio 20 according to one embodiment of the present invention. The vehicle radio 20 generates an equalized audio output signal 30 that is amplified by an amplifier 32 to generate an amplified audio output signal 36. The output signal 36 is output as sound, such as music, by one or more speakers 40. The radio 20 may also be equipped with one or more broadcast receiver(s), DVD player, CD player, tape player or other sources of audio signals as should be apparent to those skilled in the art. The audio entertainment system 10 may be integrated with other vehicle systems, such as a navigation system.

The vehicle radio 20 also has an equalizer 28 configured with first equalization settings. According to one embodiment, the equalizer 28 may be implemented as a digital signal processor (DSP) that processes vehicle equalization (EQ) data. The equalizer 28 may also process user preference equalization settings. According to other embodiments, the equalizer 28 may be implemented by any combination of analog circuitry or other digital processing circuitry that is able to accept and interpret the final equalization vector determined.

The audio entertainment system 10 is shown having a second audio device 12 coupled to the vehicle radio 20. The second audio device 12 serves as an external source to provide line-level audio signals to an input of the vehicle radio 20. The line-level audio signals may be transmitted on a conventional audio cable according to one example. The external audio source device 12 may include any audio source for providing an audio signal to the vehicle radio 20 for audio output in the form of sound, such as music, within the vehicle. According to one example, the external audio source device 12 may be a digital music player, such as an iPod. According to other examples, the external audio source device 12 may include a CD or DVD player, a TV, an MP3 player or a personal video recorder, as well as other sources of audio signals.

Each of the external audio source device 12, the vehicle radio 20, and the amplifier 32 is shown having a data communication channel, shown by reference identifiers 14, 26 and 34, respectively. The data communication channels 14, 26 and 34 allow for communication between these system components on data communication line 18. The data communication line 18 allows for communication of song equalization settings, external source equalizer commands, genre data, and equalizations specific to the amplifier 32 (especially if external as shown), as well as other information to be shared with any of the external audio source device 12, vehicle radio 20 and amplifier 32. The communication channels 14, 26 and 34 may be implemented as any known communication ports, such as USB ports according to one example. The data communication may be a vehicle communication path, such as J1850 according to one example. It should be appreciated that the streamed audio is shown input from the external audio source device 12 to the vehicle radio 20 via a separate line-level audio signal 16 on an audio cable, however, the streamed line-level audio signal may be communicated to vehicle radio 20 via other communication paths, such as the data communication line 18 via USB ports. It should further be appreciated that the line-level audio signal 16 and equalization and genre data may be communicated between the external audio source device 12 and the vehicle radio 20 via any known communication path, including wire and wireless data communication, without departing from the teachings of the present invention.

The vehicle radio 20 further includes a microprocessor 22, an audio processor such as an EQ digital signal processor (DSP) 28, and memory 24, as should be evident to those skilled in the art. The microprocessor 22, DSP 28 and memory 24 may include conventional data processing and data storage. The microprocessor 22 implements the equalization algorithm(s) of the method based on the settings and genre data stored in memory 24 within vehicle radio 20 and the equalization settings and genre data received from the external audio source device 12 and/or external amplifier 32. The final equalization determined by the method is then implemented on the audio processor DSP 28.

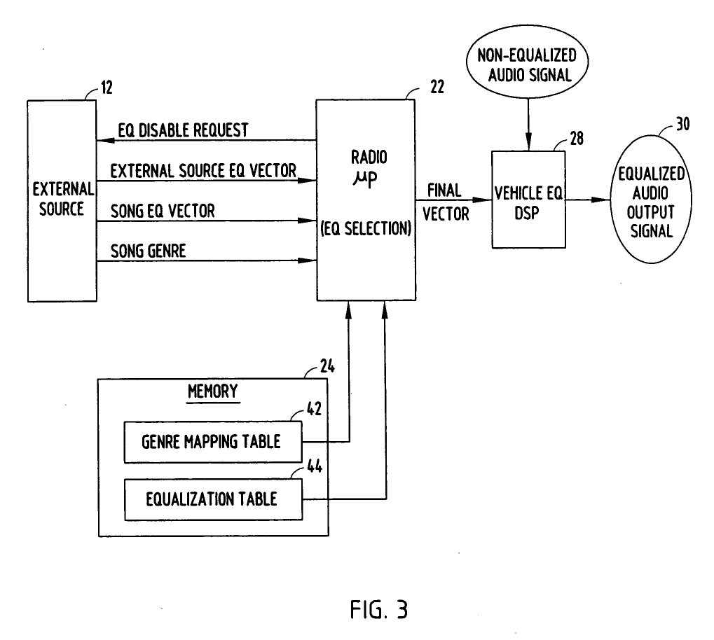

FIG. 3 details the data communications shown in FIG. 2 between the vehicle radio 20 and the external source 12 using the data communication line 18 and communication channels, according to one embodiment. Once an external audio source device 12, such as an iPod, is connected to the vehicle radio, and reliable communication is established, the vehicle radio microprocessor 22 sends an equalization disable command to request that the external audio source device 12 disables its equalization mode and report the external source equalization vector. The external audio source device 12 may return an acknowledgement that it has disabled its equalization mode and will transmit its external source equalization vector. The external device 12 may report its external source equalization vector to serve as an acknowledgement to the request. The external source equalization vector generally contains equalization settings that relate to the external device 12, but excludes the user input equalization settings of the external device 12.

As each song is played, the external audio source device 12 sends the song equalization vector, if available, with equalization settings that pertain to the individual songs. In addition, the external audio source device 12 sends the song genre (i.e., type) of music in the form of text (e.g., “rock,”“country,” etc.). The genre, external source vector and song equalization vectors are received by the vehicle radio for processing in the microprocessor 22. If the genre and song equalization settings are blank, the processor 22 uses the vehicle radio default equalization settings. If the song equalization settings, or genre and song equalization settings, are provided by the external audio source device 12, the song equalization and external source equalization vectors are included in the final equalization vector, without using genre based equalization. If the external source equalization vector is not available, and the genre is available, the song's genre is used to map a vehicle radio based genre equalization vector. This may be achieved by using the genre mapping table 42 to establish the appropriate song genre and further using the equalization table 44 to locate the proper equalization vector based on the song genre. All equalization vectors determined by the method are used to form a final equalization vector used to equalize the current audio, such as a song.

According to one example, the mapped final equalization vector may be defined by vector V̅=AV₁+BV₂+CV₃+DV₄+EV₅+FV₆, wherein variables A, B, C, D and E are weighted values for the predetermined audio frequency bands. According to one example, the audio frequency bands for V₁ to V₅ are defined in the following table:

| Band | Center Frequency |
|---|---|
| V₁ | 62.5 Hz |
| V₂ | 250 Hz |
| V₃ | 1,000 Hz |
| V₄ | 4,000 Hz |
| V₅ | 16,000 Hz |

In the above table, V₁-V₅ represents the volume in amplitude of sound to be output for each corresponding frequency band of the audio spectrum. This generally includes the equalization settings for bass sounds at low frequencies to treble sounds at high frequencies and all midrange frequencies. The weighted variables A, B, C, D and E control the amplitude of the audio output in each frequency band so as to optimize the quality of the audio, such as to minimize frequency distortions, etc. Processing of the various equalization vectors may include summing (if in decibels) or multiplying (if given as a ratio) of the elements to arrive at the final equalization vector.

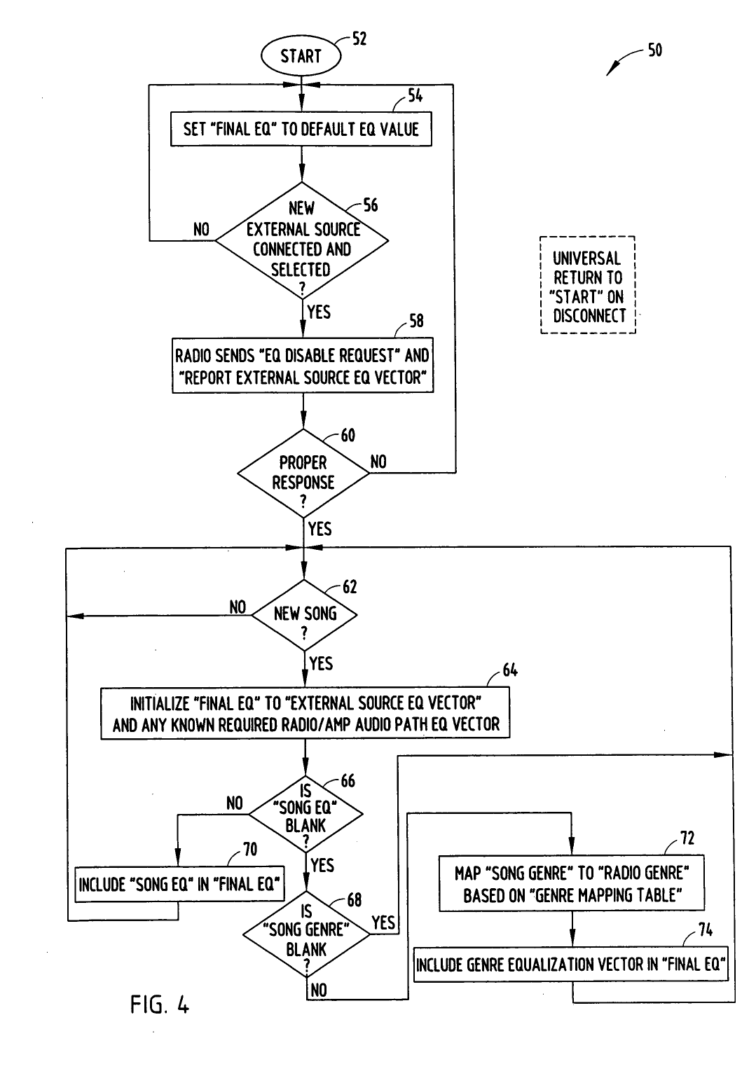

Referring to FIG. 4, a method 50 of controlling the equalization of the audio signal output by a vehicle radio provided from an external source is provided according to one embodiment. The method 50 begins at step at 52 and proceeds to set the final equalization vector to a default equalization value in step 54. Next, in decision step 56, method 50 determines if an external audio source device is connected and selected as the audio source and, if not, returns to step 54.

If the external audio source device is determined to be connected and selected as the audio source, method 50 proceeds to step 58 in which the radio sends an equalization disable request and a request for the new external audio source device to report the external source equalization vector. Next, method 50 checks if a proper response has been received in decision step 60 from the external device and, if not, assumes that the external source does not understand the protocol and returns to step 54.

Once a proper response is received, method 50 proceeds to decision step 62 to determine if a new song is present and, if not, waits for a new song. Once a new song is present, method 50 initializes the final equalization vector to the external source equalization vector and any known required radio/amplifier or audio path equalization vectors in step 64. Next, method 50 proceeds to decision step 66 to determine if the song equalization is available and, if not (blank), includes the song equalization vector in the final equalization vector in step 70 and then returns to step 62. If the song equalization is blank, method 50 proceeds to decision step 68 to determine if the song genre is blank and, if so, assumes that the listener's mood implies similar music types with similar equalization requirements as the song last played and returns to step 64. If the song genre is available (not blank), method 50 proceeds to decision step 72 to map the song genre vector to the radio genre vector based on the genre mapping table. Thereafter, method 50 includes the genre equalization vector in the final equalization vector in step 74 before returning to step 64.

Accordingly, the audio entertainment system 10 and method 50 according to the present invention advantageously allows for optimum equalization of audio, such as music, provided from an external audio source device 12, particularly for use in a vehicle. The system 10 may provide consistent equalization between multiple audio sources, and allows easy control over equalization by way of the vehicle radio 20. The resulting audio output provides a consistent volume that reduces the need for analog compensation at each of the multiple audio sources, and reduces need for user intervention, thereby resulting in less distractive operation.

It will be understood by those who practice the invention and those skilled in the art, that various modifications and improvements may be made to the invention without departing from the spirit of the disclosed concept. The scope of protection afforded is to be determined by the claims and by the breadth of interpretation allowed by law.

1. An audio entertainment system having equalization control, said system comprising:
a first audio device having an output for providing an audio output signal, wherein the first audio device has an equalizer comprising first equalization settings;
an input for receiving an audio signal from a second audio device having second equalization settings, wherein the second audio device inputs to the first audio device the second equalization settings; and
a controller for processing the first and second equalization settings and controlling the audio output signal based on at least one of the first and second equalization settings.

2. The audio entertainment system as defined in claim 1, wherein the input comprises an audio input line for receiving audio and a data communication path for receiving the second equalization settings.

3. The audio entertainment system as defined in claim 1, wherein the second audio device further inputs song genre data to the first audio device.

4. The audio entertainment system as defined in claim 1, wherein the controller generates an equalization vector indicative of the equalization settings for controlling the audio output signals at different audio frequencies.

5. The audio entertainment system as defined in claim 4, wherein the equalization vector is determined as a function of song equalization settings and the second equalization settings.

6. The audio entertainment system as defined in claim 4, wherein the equalization vector is determined as a function of song genre data.

7. The audio entertainment system as defined in claim 1, wherein the audio entertainment system is employed on a vehicle and the first audio device comprises a vehicle radio.

8. The audio entertainment system as defined in claim 1, wherein the input receives audio signals from a second audio device comprising a digital music player.

9. The audio entertainment system as defined in claim 1 further comprising an amplifier for amplifying the audio output signal and a speaker for outputting the audio signal as sound.

10. An audio entertainment system having equalization control, said system comprising:
a first audio device having an equalizer comprising first equalization settings, an input and an output for providing an audio output signal;
a second audio device coupled to the input of the first audio device for inputting an audio signal to the first audio device, wherein the second audio device further inputs second equalization settings to the first audio device; and
a controller processing the first and second equalization settings and controlling the audio output signal based on at least one of the equalization settings.

11. The audio entertainment system as defined in claim 10 further comprising an audio input line for inputting the audio to the first audio device from the second audio device and a data communication path for communicating the second equalization settings from the second audio device to the first audio device.

12. The audio entertainment system as defined in claim 10, wherein the controller generates an equalization vector indicative of the equalization settings for controlling the audio output signal at different audio frequencies, wherein the equalization vector is determined as a function of the song equalization and the second equalization settings.

13. The audio entertainment system as defined in claim 12, wherein the second audio device further inputs song genre data to the first audio device, and the equalization vector is further determined as a function of the song genre data.

14. The audio entertainment system as defined in claim 10, wherein the audio entertainment system is employed on a vehicle and the first audio device comprises a vehicle radio.

15. The audio entertainment system as defined in claim 10, wherein the second audio device comprises a digital music player.

16. The audio entertainment system as defined in claim 10 further comprising an amplifier for amplifying the audio output signal and a speaker to output the audio output signal as sound.

17. A method of generating audio at controlled equalization settings in a first audio device for an audio signal received from an external second audio device, said method comprising the steps of:
communicating an audio signal from an external second audio device to a first audio device having first equalization settings;
communicating second equalization settings from the external second audio device to the first audio device, wherein the first and second equalization settings pertain to audio levels in given frequency bands;
processing the first and second equalization settings in the first audio device; and
generating an audio output signal based on at least one of the first and second equalization settings.

18. The method as defined in claim 17, wherein the step of communicating an audio signal comprises communicating a line-level audio signal on a first communication path, and said step of communicating second equalization settings comprises communicating song equalization settings on a second communication path.

19. The method as defined in claim 17, wherein the step of communicating second equalization settings comprises communicating external source equalization settings, individual song equalization settings and genre data.

20. The method as defined in claim 17, wherein the step of processing first and second equalization settings comprises processing song equalization settings and the second equalization settings to generate an equalization vector indicative of the equalization settings for controlling the audio output signals at different audio frequencies.

21. The method as defined in claim 17 further comprising the step of processing song genre data and generating the equalization vector further as a function of the song genre data.

22. The method as defined in claim 17, wherein the step of generating an audio output signal comprises generating an equalization vector comprising equalization settings for controlling the audio output signal at different audio frequencies.

23. The method as defined in claim 17, wherein the first audio device comprises a radio employed on a vehicle, and the second audio device comprises a digital audio player.

24. The method as defined in claim 17 further comprising the step of amplifying the output audio signal and producing sound signals via a speaker.
